(19) United States
(12) Patent Application Publication
(10) Pub. No.: US 2024/0194451 A1
(43) Pub. Date: Jun. 13, 2024

(54) PLASMA PROCESSING APPARATUS, INFORMATION PROCESSING APPARATUS, PLASMA PROCESSING METHOD, AND CORRECTION METHOD

(71) Applicant: Tokyo Electron Limited, Tokyo (JP)

(72) Inventor: Taro HAYAKAWA, Yamanashi (JP)

(21) Appl. No.: 18/528,025

(22) Filed: Dec. 4, 2023

(30) Foreign Application Priority Data
Dec. 8, 2022 (JP) 2022-196395

(51) Int. Cl. H01J 37/32

(52) U.S. Cl. CPC H01J 37/3222; H01J 37/32449; H01J 37/32715

(57) ABSTRACT

A plasma processing apparatus includes a stage that is located inside a processing container and places a substrate thereon; a rotational drive mechanism that rotationally drives the stage; and a generator that is attached to a wall portion of the processing container facing the stage and generates plasma inside the processing container; an acquisition unit that acquires a processing condition including a generation period and a rotation speed of the stage; and a processing control unit that control at least one of the generation period and the rotation speed such that the stage rotates N times (N is an integer of 1 or more) during generation of the plasma, when performing the plasma processing by generating the plasma inside the processing container by the generator while rotating the stage by the rotational drive mechanism based on the processing condition acquired by the acquisition unit.

### CROSS-REFERENCE TO RELATED APPLICATIONS

This application is based on and claims priority from Japanese Patent Application No. 2022-196395, filed on Dec. 8, 2022, with the Japan Patent Office, the disclosure of which is incorporated herein in its entirety by reference.

### TECHNICAL FIELD

The present disclosure relates to a plasma processing apparatus, an information processing apparatus, a plasma processing method, and a correction method.

### BACKGROUND

Japanese Patent Laid-Open Publication No. 2013-179321 discloses a film forming method for forming a product film including a silicon nitride film inside a vacuum-maintainable processing container. The film forming method includes repeating, a plurality of times, a film forming process of forming the product film on a product processing target inside the processing container, performing a cleaning process of removing a reaction product adhering to the inside of the processing container due to the film forming process without accommodating the product processing target inside the processing container, performing a coating process of coating the inside of the processing container with a coating film including a silicon nitride film without accommodating the product processing target inside the processing container, and then performing the film forming process of forming the product film on the product processing target inside the processing container. Each of the film forming process and the coating process utilizes atomic layer deposition (ALD), which repeats, a plurality of times, a cycle including a first supply step and a second supply step alternately with a purge step therebetween. In the first supply step, a monochlorosilane gas is supplied as a Si source gas into the processing container, and in the second supply step, a nitrogen-containing gas is supplied as a nitriding gas into the processing container. The coating process is performed by thermal ALD in which the Si source gas and the nitriding gas are supplied into the processing container without undergoing plasma generation.

### SUMMARY

A plasma processing apparatus according to one aspect disclosed herein includes a stage, a rotational drive mechanism, a generator, an acquisition unit, and a processing control unit. The stage is located inside a processing container and is configured to place a substrate thereon. The rotational drive mechanism rotationally drives the stage. The generator is attached to a wall portion of the processing container facing the stage and generates plasma inside the processing container. The acquisition unit acquires a processing condition including a generation period and a rotation speed of the stage as the processing condition for a plasma processing in which the generation period during which plasma is generated inside the processing container and a non-generation period during which no plasma is generated are alternately repeated a plurality of times. The processing control unit controls at least one of the generation period by the generator and the rotation speed such that the stage rotates N times (N is an integer of 1 or more) during generation of the plasma inside the processing container, when the plasma processing is performed by generating the plasma inside the processing container by the generator while rotating the stage by the rotational drive mechanism based on the processing condition acquired by the acquisition unit.

Further, an information processing apparatus according to another aspect disclosed herein includes a reception unit and a correction unit. The reception unit is configured to receive an input of a generation period and a rotation speed of a stage as a processing condition for a plasma processing in which the generation period during which a plasma is generated inside a processing container and a non-generation period during which no plasma is generated are alternately repeated a plurality of times while rotating the stage located inside the processing container to place a substrate thereon. The correction unit is configured to correct at least one of the generation period and the rotation speed of the stage received from the reception unit, to ensure that the stage rotates N times (N is an integer of 1 or more) during generation of the plasma inside the processing container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view schematically illustrating an example of a plasma processing apparatus according to a first embodiment.

FIG. 2 is a diagram illustrating an example of the arrangement of microwave radiation mechanisms in a ceiling wall portion according to the first embodiment.

FIG. 3 is a diagram illustrating an example of conventional plasma processing.

FIG. 4 is a diagram illustrating an example of plasma distribution used in a simulation.

FIG. 5A is a diagram illustrating an example of the simulation results for the amount of plasma irradiation.

FIG. 5B is a diagram illustrating an example of the simulation results for the amount of plasma irradiation.

FIG. 5C is a diagram illustrating an example of the simulation results for the amount of plasma irradiation.

FIG. 6 is a flowchart illustrating an example of the flow of plasma processing according to the first embodiment.

FIG. 7 is a cross-sectional view schematically illustrating an example of a plasma processing apparatus according to a second embodiment.

FIG. 8 is a flowchart illustrating an example of the flow of a correction method according to the second embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of a plasma processing apparatus, an information processing apparatus, a plasma processing method, and a correction method disclosed herein will be described in detail with reference to the accompanying drawings. The disclosed plasma processing apparatus, information processing apparatus, plasma processing method, and correction method are not limited by these embodiments.

A plasma processing apparatus is devised to generate a plasma inside a chamber and to perform a plasma processing on a substrate such as a semiconductor wafer placed on a stage inside the chamber. However, there are cases where uneven plasma generation inside the chamber causes the non-uniform amount of plasma irradiation to the substrate. Therefore, some plasma processing apparatuses are adapted to have a rotatable stage, allowing the stage to rotate while generating a plasma inside the chamber, which helps to equalize the amount of plasma irradiation in the circumferential direction of the substrate.

However, the rotation of the stage has typically been controlled regardless of the ON/OFF state of plasma. Therefore, even when the stage is rotated for a generation period during which the plasma is being generated, the stage may not complete a full rotation by the end of the generation period, which may result in an inability to equalize the amount of plasma irradiation in the circumferential direction of the substrate.

Accordingly, there is an expectation for technology to equalize the amount of plasma irradiation in the circumferential direction of a substrate.

### First Embodiment

### [Apparatus Configuration]

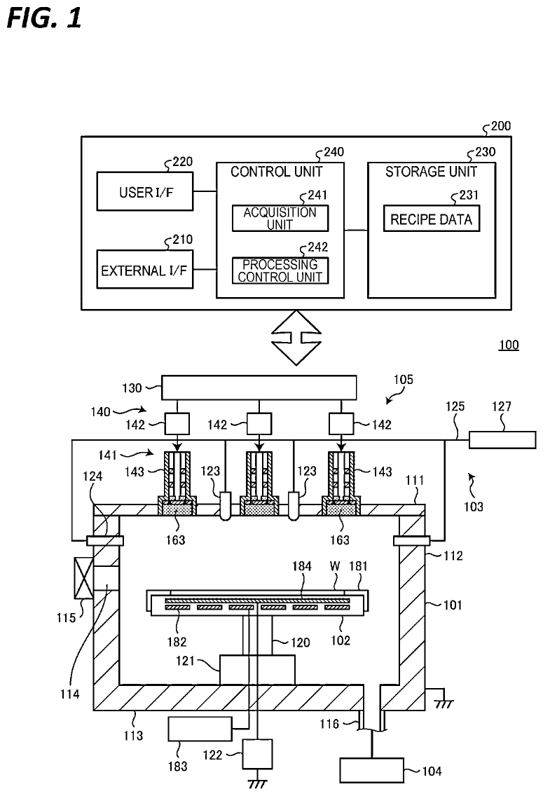

First, a first embodiment will be described. FIG. 1 is a cross-sectional view schematically illustrating an example of a plasma processing apparatus 100 according to a first embodiment. The plasma processing apparatus 100 is an apparatus that generates a plasma using microwaves. The plasma processing apparatus 100 illustrated in FIG. 1 includes a processing container 101, a stage 102, a gas supply mechanism 103, an exhaust device 104, a microwave introduction device 105, and a controller 200.

The processing container 101 accommodates a substrate W such as a semiconductor wafer. The stage 102 is located inside the processing container 101. The substrate W is placed on the stage 102. In the embodiment, the stage 102 corresponds to a stage disclosed herein.

The gas supply mechanism 103 supplies gases into the processing container 101. The exhaust device 104 evacuates the processing container 101. The microwave introduction device 105 generates microwaves for generating a plasma inside the processing container 101 and introduces the microwaves into the processing container 101. The controller 200 controls the operation of each part of the plasma processing apparatus 100.

The processing container 101 is made of, for example, a metal material such as aluminum and an alloy thereof and has a substantially cylindrical shape. The processing container 101 has a plate-shaped ceiling wall portion 111 and bottom wall portion 113, and a sidewall portion 112 connecting the two. An inner wall of the processing container 101 is coated with a protective film such as yttria (Y₂O₃).

The microwave introduction device 105 is provided on the top of the processing container 101 and serves to introduce electromagnetic waves (microwaves) into the processing container 101 to generate a plasma. Further details regarding the microwave introduction device 105 will be described later.

The ceiling wall portion 111 has a plurality of openings into which microwave radiation mechanisms 143 and gas introduction nozzles 123, which will be described later, of the microwave introduction device 105 are fitted. The sidewall portion 112 has a loading/unloading port 114 for loading and unloading the substrate W between the processing container 101 and an adjacent transfer chamber (not illustrated). Further, the sidewall portion 112 is provided with a gas introduction nozzle 124 at a position above the stage 102. The loading/unloading port 114 is opened and closed by a gate valve 115.

The bottom wall 113 has an opening and is provided with the exhaust device 104 via an exhaust pipe 116 connected to the opening. The exhaust device 104 includes a vacuum pump and a pressure control valve. The processing container 101 is evacuated through the exhaust pipe 116 by the vacuum pump of the exhaust device 104. The pressure inside the processing container 101 is controlled by the pressure control valve of the exhaust device 104.

The stage 102 is formed in a disk shape. The stage 102 is made of a dielectric. For example, the stage 102 is made of surface-anodized aluminum or ceramics such as aluminum nitride (AlN). The substrate W is placed on an upper surface of the stage 102. The stage 102 is supported at a central portion of a lower surface thereof by a cylindrical support member 120 made of ceramics such as AlN. A rotational drive mechanism 121 is provided at the bottom center of the processing container 101. The rotational drive mechanism 121 rotatably supports the support member 120. The stage 102 is rotatably supported by both the support member 120 and the rotational drive mechanism 121. The rotational drive mechanism 121 has a built-in motor and rotates the support member 120 using the drive force of the motor, thereby rotating the stage 102. The stage 102 rotates in the circumferential direction with the center axis of the disk shape as the rotation axis. A guide ring 181 is provided on the outer edge of the stage 102 to guide the substrate W. Further, a lifting pin (not illustrated) for lifting the substrate W is provided inside the stage 102 so as to protrude and retract relative to the upper surface of the stage 102.

A resistance heating type heater 182 is embedded in the stage 102. Further, an electrode 184 having approximately the same size as the substrate W is embedded in the stage 102 above the heater 182. Further, a thermocouple (not illustrated) is inserted into the stage 102. The heater 182, the electrode 184, and the thermocouple are electrically connected to the rotational drive mechanism 121 through the support member 120. For example, a slip ring is provided in the rotational drive mechanism 121, enabling electrical connection to wirings connected to the heater 182, the electrode 184, and the thermocouple. The heater 182 is connected to a heater power supply 183 through the rotational drive mechanism 121. The electrode 184 is connected to a DC power source 122 through the rotational drive mechanism 121. The thermocouple is connected to the controller 200 through the rotational drive mechanism 121. The heater 182 heats the substrate W placed on the stage 102 upon receiving power from the heater power supply 183. Further, the stage 102 is capable of controlling the heating temperature of the substrate W based on a signal from the thermocouple. The DC power source 122 periodically applies a direct current voltage to the electrode 184 inside the stage 102. For example, the DC power source 122 includes a DC power supply and a pulse unit. The DC power source 122 turns the DC voltage supplied by the DC power supply on and off by the pulse unit to periodically apply a pulse-shaped DC voltage to the electrode 184.

The gas supply mechanism 103 supplies various gases into the processing container 101. The gas supply mechanism 103 includes gas introduction nozzles 123 and 124, a gas supply pipe 125, and a gas supply 127. The gas introduction nozzles 123 are fitted into the openings formed in the ceiling wall portion 111 of the processing container 101. The gas introduction nozzle 124 is fitted into an opening formed in the sidewall portion 112 of the processing container 101. One end of the gas supply pipe 125 is connected to the gas supply 127. The gas supply pipe 125 is branched at the other end side and is connected at the other end thereof to the respective gas introduction nozzles 123 and 124. The gas supply 127 includes various gas sources. Further, the gas supply 127 includes on-off vales for starting and stopping the supply of various gases and flow adjusters for adjusting the flow rates of the gases. The gas supply 127 supplies various gases such as processing gases used in a plasma processing.

The microwave introduction device 105 is provided above the processing container 101. The microwave introduction device 105 introduces electromagnetic waves (microwaves) into the processing container 101 to generate a plasma. In the embodiment, the microwave introduction device 105 corresponds to a generator disclosed herein.

The microwave introduction device 105 includes a microwave output part 130 and an antenna unit 140. The microwave output part 130 generates microwaves and distributes and outputs the microwaves to a plurality of paths. The antenna unit 140 introduces the microwaves output from the microwave output part 130 into the processing container 101.

The microwave output part 130 includes a microwave power supply, a microwave oscillator, an amplifier, and a distributor. The microwave oscillator is a solid-state device that generates microwave oscillation (e.g., PLL oscillation) at a frequency of, for example, 860 MHz. The frequency of microwaves is not limited to 860 MHz and may be within the range of 700 MHz to 10 GHz such as 2.45 GHZ, 8.35 GHz, 5.8 GHz, and 1.98 GHz. The amplifier amplifies the microwaves oscillated by the microwave oscillator. The distributor distributes the microwaves amplified by the amplifier to a plurality of paths. The distributor distributes the microwaves while matching the impedance between the input side and the output side.

The antenna unit 140 includes a plurality of antenna modules 141. FIG. 1 illustrates three antenna modules 141 of the antenna unit 140.

Each antenna module 141 includes an amplifier part 142 and the microwave radiation mechanism 143. The microwave output part 130 generates microwaves and also distributes the microwaves to output them to each antenna module 141. The amplifier part 142 mainly amplifies the distributed microwaves to output them to the microwave radiation mechanism 143. The microwave radiation mechanism 143 is attached to the ceiling wall portion 111. The microwave radiation mechanism 143 radiates the microwaves output from the amplifier part 142 into the processing container 101. In the embodiment, the ceiling wall portion 111 corresponds to a wall portion of the processing container 101 disclosed herein.

The amplifier part 142 includes a phase shifter, a variable gain amplifier, a main amplifier, and an isolator. The phaser shifter alters the phase of microwaves. The variable gain amplifier adjusts the power level of microwaves input to the main amplifier. The main amplifier is configured as a solid-state amplifier. The isolator separates reflected microwaves directed toward the main amplifier from an antenna part of the microwave radiation mechanism 143 to be described later.

A plurality of microwave radiation mechanisms 143 are provided in the ceiling wall portion 111. Further, each microwave radiation mechanism 143 includes a cylindrical outer conductor and an inner conductor provided coaxially inside the outer conductor. Further, the microwave radiation mechanism 143 includes a coaxial tube having a microwave transmission path between the outer conductor and the inner conductor and the antenna part for radiating microwaves into the processing container 101. A microwave transparent plate 163 fitted into the ceiling wall portion 111 is provided at the lower surface side of the antenna part. A lower surface of the microwave transparent plate 163 is exposed to the internal space of the processing container 101. The microwaves transmitted through the microwave transparent plate 163 generate a plasma in the internal space of the processing container 101.

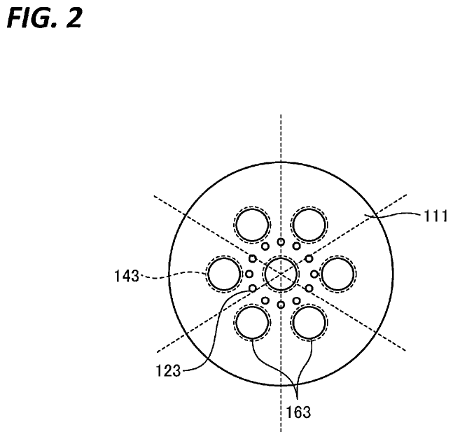

FIG. 2 is a diagram illustrating an example of the arrangement of the microwave radiation mechanisms 143 in the ceiling wall portion 111 according to the first embodiment. As illustrated in FIG. 2, seven microwave radiation mechanisms 143 of the antenna unit 140 are provided in the ceiling wall portion 111. Six of the microwave radiation mechanisms 143 are positioned at the vertices of a regular hexagon and one is positioned at the center position of the regular hexagon. The center position of the regular hexagon is the position through which the rotation axis of the stage 102 passes. In the antenna unit 140 according to the embodiment, the plurality of antenna modules 141 are arranged symmetrically about the rotation axis of the stage 102.

Further, there are microwave transparent plates 163 arranged in the ceiling wall portion 111 to correspond to the seven microwave radiation mechanisms 143, respectively. These seven adjacent microwave transparent plates 163 are arranged equidistantly from each other. Further, the multiple gas introduction nozzles 123 of the gas supply mechanism 103 are arranged to surround the central microwave transparent plate 163. The number of antenna modules 141 provided on the ceiling wall portion 111 is not limited to seven.

A description will continue, returning to FIG. 1. The antenna unit 140 is capable of adjusting the power of microwaves radiated from the microwave radiation mechanism 143 of each antenna module 141 by controlling the amplifier part 142 of each antenna module 141.

The operation of the plasma processing apparatus 100 configured as described above is comprehensively controlled by the controller 200.

The controller 200 is, for example, an information processing apparatus such as a computer. The controller 200 is equipped with an external interface (I/F) 210, a user I/F 220, a storage unit 230, and a control unit 240.

The external I/F 210 is an interface that inputs and outputs various types of information. For example, the external I/F 210 includes an input/output port such as a universal serial bus (USB) port and a communication interface such as a LAN port. The external I/F 210 inputs and outputs various types of information to and from each part of the plasma processing apparatus 100. Further, the external I/F 210 is connected to a network (not illustrated) to transmit and receive various types of information to and from other devices through the network.

The user I/F 220 includes an input part such as a keyboard that is used by a process manager to input commands for managing the plasma processing apparatus 100 and a display part such as a display that visually displays the operational status of the plasma processing apparatus 100. The user I/F 220 receives the input of various types of information.

The storage unit 230 is a storage device that stores various types of data. For example, the storage unit 230 is a storage device such as a hard disk, solid state drive (SSD), or optical disk. The storage unit 230 may also be a data rewritable semiconductor memory such as a random access memory (RAM), flash memory, or non-volatile static random access memory (NVSRAM).

The storage unit 230 stores a control program (software) and various other programs for implementing various processes executed in the plasma processing apparatus 100 under the control of the control unit 240. Further, the storage unit 230 stores various types of data used in the programs executed by the control unit 240. For example, the storage unit 230 stores recipe data 231 that stores, for example, plasma processing conditions. Programs and data may be stored in computer-readable computer recording media (e.g., hard disks, optical disks such as DVDs, flexible disks, semiconductor memories, etc.). Further, programs and data may also be transmitted in real time from other devices such as through dedicated lines for online use.

The control unit 240 includes a central processing unit (CPU) and a memory and controls each part of the plasma processing apparatus 100. The control unit 240 reads the control program stored in the storage unit 230 and executes the processing of the read control program. The control unit 240 controls each part of the plasma processing apparatus 100 according to the processing of the control program. For example, the control unit 240 controls each part of the plasma processing apparatus 100 to perform a plasma processing according to the recipe data 231 stored in the storage unit 230. The control unit 240 functions as various processors through the operation of the control program. For example, the control unit 240 has the functions of an acquisition unit 241 and a processing control unit 242. In the present embodiment, a case where the control unit 240 has the functions of the acquisition unit 241 and the processing control unit 242 will be described by way of example. However, the functions of the acquisition unit 241 and the processing control unit 242 may also be implemented by a plurality of controllers in a distributed manner. For example, the acquisition unit 241 and the processing control unit 242 may be implemented in a distributed manner by separate controllers that are capable of data communication with each other.

The acquisition unit 241 acquires the recipe data 231. In the present embodiment, the recipe data 231 is stored in the storage unit 230. The acquisition unit 241 acquires the recipe data 231 by reading it from the storage unit 230. When the recipe data 231 is stored in another device, the acquisition unit 241 acquires the recipe data 231 from the other device through the external I/F 210.

The recipe data 231 stores plasma processing conditions. For example, the recipe data 231 stores processing conditions such as the types of gases used in a plasma processing, the flow rates of gases, the rotation speed of the stage 102, the ON/OFF periods of plasma, and the power of microwaves used in plasma generation. In the present embodiment, the recipe data 231 stores processing conditions for plasma enhanced atomic layer deposition (PEALD) as a plasma processing. In PEALD, film formation is performed by alternately repeating, a plurality of times, a generation period during which a plasma is generated inside the processing container 101 and a non-generation period during which no plasma is generated inside the processing container 101.

The processing control unit 242 controls each part of the plasma processing apparatus 100 and performs a plasma processing based on the recipe data 231 acquired by the acquisition unit 241. For example, the processing control unit 242 controls the rotational drive mechanism 121 and rotates the stage 102 by the rotational drive mechanism 121 based on the recipe data 231. Further, the processing control unit 242 controls the gas supply mechanism 103 and supplies various gases from the gas supply mechanism 103 into the processing container 101. Further, the processing control unit 242 controls the microwave introduction device 105 and introduces microwaves from the microwave introduction device 105 into the processing container 101 to generate a plasma using the microwaves inside the processing container 101. The processing control unit 242 generates a plasma inside the processing container 101 while rotating the stage 102 to perform a plasma processing on the substrate W placed on the stage 102.

Here, in conventional PEALD, the rotation of the stage 102 has typically been controlled regardless of the ON/OFF state of plasma. Therefore, even when the stage 102 is rotated during a plasma generation period, the stage 102 may not complete a full rotation by the end of the generation period, which may result in an inability to equalize the amount of plasma irradiation in the circumferential direction of the substrate W.

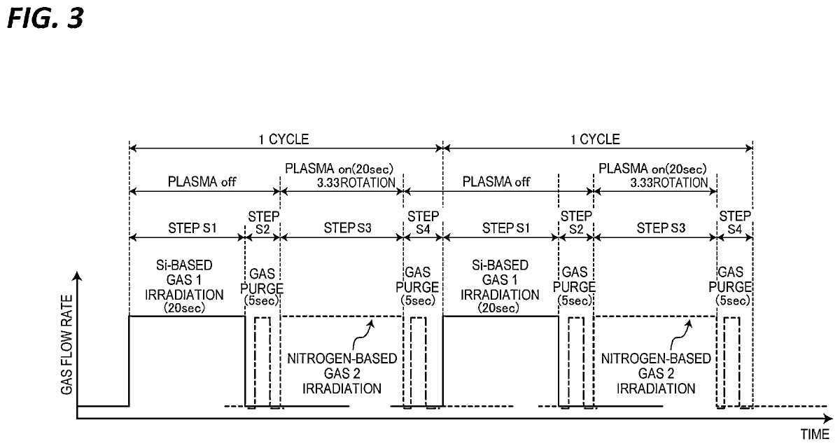

FIG. 3 is a diagram illustrating an example of conventional plasma processing. FIG. 3 illustrates an example of the procedure for forming a silicon nitride film by PEALD as a plasma processing. In PEALD, a processing from step S1 to step S4 is performed. FIG. 3 schematically illustrates the types and the flow rates of gases used in steps S1 to S4.

In step S1, no plasma is generated inside the processing container 101 to reach the OFF state of plasma, and a silicon (Si)-based gas is supplied into the processing container 101. Step S1 lasts, for example, 20 seconds. In step S2, in the OFF state of plasma, a purge gas is supplied into the processing container 101 to purge (exhaust) the Si-based gas supplied in step S1. Step S2 lasts, for example, 5 seconds. In step S3, a nitrogen-based gas is supplied into the processing container 101, and a plasma is generated inside the processing container 101 to reach the ON state of plasma. Step S3 lasts, for example, 20 seconds. In step S4, no plasma is generated inside the processing container 101 to reach the OFF state of plasma, and a purge gas is supplied into the processing container 101 to purge the nitrogen-based gas supplied in step S3. Step S4 lasts, for example, 5 seconds.

In PEALD, for example, while the stage 102 is rotated at a speed of 10 [rpm](≈0.17 [rotation/sec]), steps S1 to S4 constituting one cycle are repeated a plurality of times. In FIG. 3, only two cycles are illustrated, but the cycle is repeated until a predetermined termination condition is satisfied. The termination condition may be a certain number of cycles, or may a certain thickness of a film to be formed. In this case, in step S3, the stage 102 rotates 3.33 times during a generation period (20s) when the plasma is being generated inside the processing container 101. In step S3, at the end of the generation period, the stage rotates only 0.33 of a full rotation, which may result in an inability to equalize the amount of plasma irradiation in the circumferential direction.

In a plasma processing, when the amount of plasma irradiation in the circumferential direction is uneven, it may lead to non-uniform plasma processing results in the circumferential direction of the substrate W. For example, in PEALD, when the amount of plasma irradiation in the circumferential direction is uneven, the film quality in the circumferential direction of the substrate W is non-uniform.

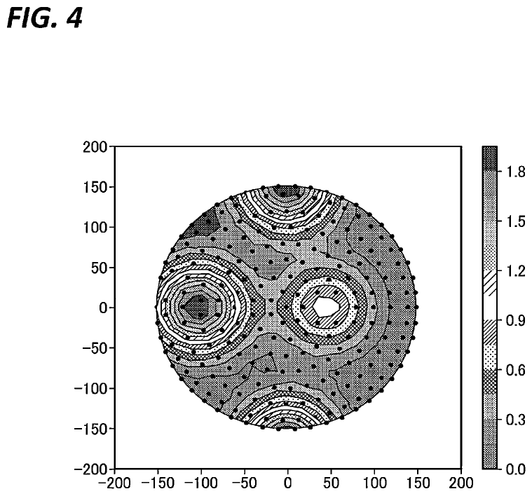

An example of the simulation results for the amount of plasma irradiation will be described. In this simulation, unlike FIG. 2, the microwave radiation mechanisms 143 were arranged such that four microwave radiation mechanisms 143 were arranged asymmetrically relative to the rotation axis of the stage 102 to perform plasma irradiation individually. FIG. 4 is a diagram illustrating an example of plasma distribution used in the simulation. FIG. 4 illustrates plasma distribution on the stage 102 when the stage 102 is not rotating. The plasma distribution exhibits higher plasma in a region below the antenna module 141 and becomes significantly uneven in the plane of the stage 102.

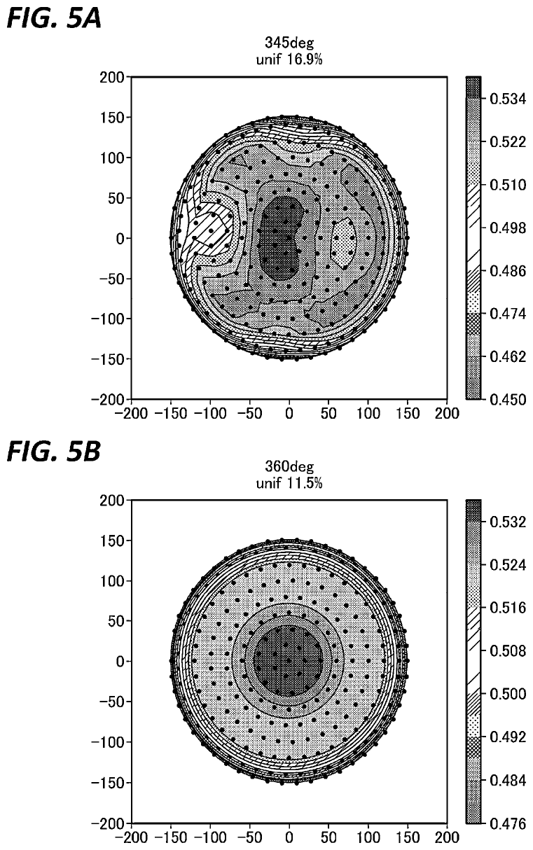

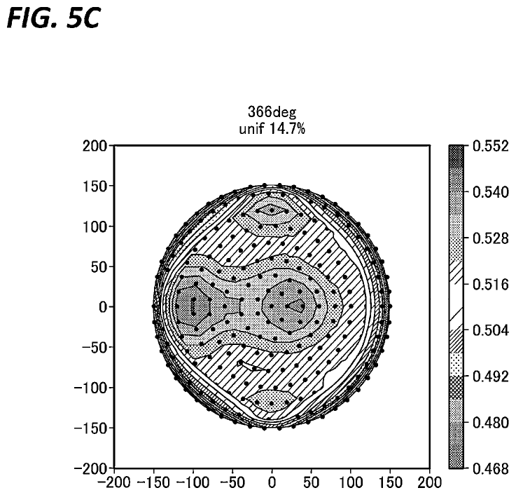

FIGS. 5A to 5C are diagrams illustrating an example of the simulation results for the amount of plasma irradiation. FIGS. 5A to 5C illustrate the distribution of the amount of plasma irradiation on the surface of the stage 102 in respective cases where the stage 102 is rotated at a constant speed during plasma irradiation according to the plasma distribution of FIG. 4.

FIG. 5A illustrates a case where the stage 102 is rotated by 354 degrees. In FIG. 5A, there are regions in the circumferential direction of the stage 102 where the amount of plasma irradiation varies. FIG. 5B illustrates a case where the stage 102 is rotated by 360 degrees. In FIG. 5B, the amount of plasma irradiation is uniform in the circumferential direction of the stage 102. FIG. 5C illustrates a case where the stage 102 is rotated by 366 degrees. In FIG. 5C, there are regions in the circumferential direction of the stage 102 where the amount of plasma irradiation varies.

Further, FIGS. 5A to 5C illustrate the uniformity of the amount of plasma irradiation (unif=(max−min)/average) in the plane of the stage 102. The uniformity of the amount of plasma irradiation is lowest in FIG. 5B where the stage 102 is rotated by 360 degrees (one full rotation). In FIG. 5B, although the amount of plasma irradiation is uniform in the circumferential direction of the stage 102, the uniformity is 11.5% due to a difference in the amount of plasma irradiation between the center side and the outer side in the radial direction of the stage 102. The difference in the amount of plasma irradiation between the center side and the outer side may be adjusted to increase the uniformity (reduce the value of Unif) by adjusting the plasma distribution as illustrated in FIG. 4.

As can be seen from the simulation results illustrated in FIGS. 5A to 5C, the stage 102 is rotated in 360-degree increments during plasma irradiation, leading to uniform plasma irradiation in the circumferential direction of the stage 102. Accordingly, it is possible to equalize the amount of plasma irradiation in the circumferential direction of the substrate W by rotating the stage 102 in 360-degree increments while the plasma is being generated inside the processing container 101.

Accordingly, when a plasma processing is performed, the processing control unit 242 controls at least one of the plasma generation period and the rotation speed of the stage 102, to ensure that the stage 102 rotates N times (N is an integer of 1 or more) during plasma generation inside the processing container 101. For example, the processing control unit 242 corrects at least one of the plasma generation period and rotation speed in the recipe data 231 acquired by the acquisition unit 241, to ensure that the stage 102 rotates N times during plasma generation inside the processing container 101.

A specific example will be described. In the recipe data 231, the period for plasma generation inside the processing container 101 is denoted as Tpla [sec], and the rotation speed of the stage 102 is denoted as V [rotation/sec]. The rotation speed V is taken as the number of rotations per second.

The processing control unit 242 calculates the number of rotations of the stage 102 during the generation period by multiplying the generation period and the rotation speed of the stage 102 in the recipe data 231. For example, the processing control unit 242 multiplies Tpla and V (Tpla×V) to calculate the number of rotations of the stage 102. For example, when Tpla is 1.5 and V is 0.5, the processing control unit 242 calculates Tpla×V as 1.5×0.5=0.75.

The processing control unit 242 performs rounding of the calculated number of rotations to an integer of 1 or more. For example, the processing control unit 242 performs rounding of the calculated Tpla×V to convert Tpla×V to an integer of 1 or more. The rounding may take various forms as long as it converts Tpla×V to an integer of 1 or more. Examples of the rounding may include truncation, rounding-up, and rounding to the nearest decimal. For example, when Tpla×V is less than 0.5, the processing control unit 242 rounds it up to 1. Further, when Tpla×V is 0.5 or higher, the processing control unit 242 rounds it to the nearest integer. For example, when Tpla×V is 0.75, the processing control unit 242 rounds it to 1.0.

The processing control unit 242 corrects the rotation speed V in the recipe data 231 to a value obtained by dividing the integer resulting from the rounding by the generation period. For example, the processing control unit 242 calculates a value by dividing the integer resulting from the rounding by Tpla, and corrects the rotation speed V in the recipe data 231 to the calculated value. For example, when the integer resulting from the rounding is 1.0, the processing control unit 242 corrects the rotation speed in the recipe data 231 to 1.0/1.5=⅔≈0.66 [rotation/sec].

The processing control unit 242 controls each part of the plasma processing apparatus 100 and performs a plasma processing based on the corrected recipe data 231. For example, the processing control unit 242 rotates the stage 102 at the rotation speed in the corrected recipe data 231 by the rotational drive mechanism 121. While rotating the stage 102, the processing control unit 242 introduces microwaves from the microwave introduction device 105 into the processing container 101 during the generation period in the recipe data 231 to generate a plasma using the microwaves inside the processing container 101. For example, the processing control unit 242 introduces microwaves into the processing container 101 for 1.5 seconds while rotating the stage 102 at ⅔ [rotation/sec] to generate a plasma using the microwaves inside the processing container 101.

In this way, the stage 102 rotates N times (integer times) during plasma generation inside the processing container 101, which allows for equalizing the amount of plasma irradiation in the circumferential direction of the substrate W.

In the case of FIG. 3, the processing control unit 242 calculates Tpla×V as 20×0.17=3.4. The processing control unit 242 performs rounding to convert 3.4 to 3.0. The processing control unit 242 corrects the rotation speed in the recipe data 231 to be 3/0/20=0.15 [rotation/sec]. In this way, in step S3 of FIG. 3, the number of rotations is 3.0 times(=0.15×20), which helps to equalize the amount of plasma irradiation in the circumferential direction of the substrate W.

The processing control unit 242 may correct the generation period in the recipe data 231 acquired by the acquisition unit 241, to ensure that the stage 102 rotates N times during plasma generation inside the processing container 101. For example, the processing control unit 242 calculates the time it takes for the stage 102 to rotate N times when the stage 102 is rotated at the rotation speed in the recipe data 231. For example, the processing control unit 242 calculates the time required for the number of rotations of the stage 102 to firstly become an integer beyond the generation period in the recipe data 231. Then, the processing control unit 242 may correct the generation period in the recipe data 231 based on the calculated time.

Further, the processing control unit 242 may correct both the generation period and rotation speed in the recipe data 231 acquired by the acquisition unit 241, to ensure that the stage 102 rotates N times during plasma generation inside the processing container 101. For example, when the rotation speed of the stage 102 is changeable stepwise, the processing control unit 242 corrects the rotation speed in the recipe data 231 to the changeable rotation speed. For example, the processing control unit 242 corrects the rotation speed in the recipe data 231 to the nearest changeable rotation speed. Then, the processing control unit 242 calculates the time required for the stage 102 to rotate N times when the stage 102 is rotated at the corrected rotation speed. For example, the processing control unit 242 calculates the time required for the number of rotations of the stage 102 to firstly become an integer beyond the generation period in the recipe data 231. Then, the processing control unit 242 may correct the generation period in the recipe data 231 based on the calculated time.

In PEALD, a generation period during which a plasma is generated inside the processing container 101 and a non-generation period during which no plasma is generated inside the processing container 101 are alternately repeated a plurality of times. The plasma processing apparatus 100 according to the present embodiment may equalize the amount of plasma irradiation in the circumferential direction of the substrate W since the stage 102 rotates N times during each plasma generation period.

### [Plasma Processing Method]

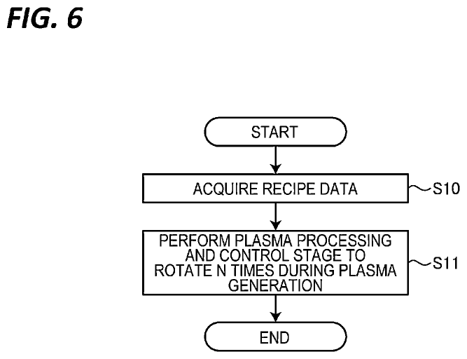

Next, the flow of a plasma processing by a plasma processing method according to the first embodiment will be described. FIG. 6 is a flowchart illustrating an example of the flow of plasma processing according to the first embodiment. The processing in FIG. 6 is executed when performing a plasma processing. In the plasma processing apparatus 100, when performing a plasma processing, the substrate W, which is a plasma processing target, is placed on the stage 102.

The acquisition unit 241 acquires the recipe data 231 (step S10). For example, the acquisition unit 241 acquires the recipe data 231 by reading it from the storage unit 230.

The processing control unit 242 generates a plasma inside the processing container 101 while rotating the stage 102 to perform a plasma processing on the substrate W placed on the stage 102, based on the acquired recipe data 231. Further, when performing the plasma processing, the processing control unit 242 controls at least one of the plasma generation period and the rotation speed of the stage 102, to ensure that the stage 102 rotates N times during plasma generation inside the processing container 101 (step S11). When the plasma processing is completed, the processing illustrated in this flowchart is terminated.

However, there are cases where the plasma processing apparatus 100 is configured such that the plasma distribution on the stage 102 exhibits rotational symmetry of M times (M is an integer of 2 or more) about the rotation axis of the stage 102. For example, in the microwave introduction device 105 according to the embodiment, as illustrated in FIG. 2, the microwave radiation mechanisms 143 are positioned at the vertices and center position of a regular hexagon, creating the arrangement of six-time rotational symmetry. FIG. 2 illustrates the positions where the microwave radiation mechanisms 143 are linearly symmetrically arranged with dashed lines. Therefore, in the plasma processing apparatus 100 according to the embodiment, the plasma distribution on the stage 102 corresponds to six-time rotational symmetry about the rotation axis of the stage 102.

When the plasma distribution corresponds to M-time rotational symmetry, the processing control unit 242 may control at least one of the plasma generation period and the rotation speed of the stage 102, to ensure that the stage 102 rotates N/M times during plasma generation inside the processing container 101. For example, the processing control unit 242 corrects at least one of the generation period and the rotation speed in the recipe data 231 acquired by the acquisition unit 241, to ensure that the stage 102 rotates N/M times during plasma generation inside the processing container 101.

A specific example will be described. In the recipe data 231, the plasma generation period is denoted as Tpla [sec], and the rotation speed of the stage 102 is denoted as V [rotation/sec].

The processing control unit 242 calculates a multiplication value by multiplying the generation period, the rotation speed of the stage 102, and the rotational symmetry number M in the recipe data 231. For example, the processing control unit 242 multiplies Tpla, V and M to calculate a multiplication value as Tpla×V×M. For example, when Tpla is 1.5, V is 0.5, and M is 6, the processing control unit 242 calculates Tpla×V×M as 1.5×0.5×6=4.5.

The processing control unit 242 performs rounding of the calculated multiplication value to an integer of 1 or more. For example, the processing control unit 242 performs rounding on the calculated Tpla×V×M to convert it to an integer of 1 or more. The rounding may take various forms as long as it converts Tpla×V×M to an integer of 1 or more. For example, when Tpla×V×M is 4.5, the processing control unit 242 rounds it up to 5.0.

The processing control unit 242 corrects the rotation speed V in the recipe data 231 to a value obtained by dividing the integer resulting from the rounding of the multiplication value by the generation period and the rotational symmetry number M. For example, the processing control unit 242 calculates a value by dividing the integer resulting from the rounding of the multiplication value by Tpla and M, and corrects the rotation speed V in the recipe data 231 to the calculated value. For example, when the integer resulting from the rounding of the multiplication value is 5.0, the processing control unit 242 corrects the rotation speed in the recipe data 231 to 5.0/(1.5×6)≈0.55 [rotation/sec].

In this way, the stage 102 rotates N/M times during plasma generation inside the processing container 101, which allows for equalizing the amount of plasma irradiation in the circumferential direction of the substrate W.

Further, the processing control unit 242 may perform the following control when performing a plasma processing according to the recipe data 231 stored in the storage unit 230. The processing control unit 242 stores the rotation position of the stage 102 at the start timing when the microwave introduction device 105 starts plasma generation inside the processing container 101. Then, the processing control unit 242 may perform control to terminate the plasma generation by the microwave introduction device 105 at the timing when the rotation position of the stage 102 reaches the rotation position at the start timing after the generation period in the recipe data 231 has passed.

In this way, the stage 102 rotates N times during plasma generation inside the processing container 101, which allows for equalizing the amount of plasma irradiation in the circumferential direction of the substrate W.

By the way, the plasma processing apparatus 100 generates a plasma inside the processing container 101 during the generation period in the recipe data 231. Immediately after plasma generation, there is an initial state until the plasma stabilizes. As described above, in PEALD, a generation period during which a plasma is generated inside the processing container 101 and a non-generation period during which no plasma is generated inside the processing container 101 are alternately repeated a plurality of times. In the plasma processing apparatus 100, the stage 102 rotates N times during each generation period. In this case, when the rotation position of the stage 102 at the start timing of each generation period is always the same, the stage is at the same rotation position in the initial state immediately after plasma generation, which may result in non-uniform plasma processing results for the substrate W.

Accordingly, when performing a plasma processing based on the recipe data 231, the processing control unit 242 may control the length of the non-generation period such that the rotation position of the stage 102 at the start timing of each generation period of the plasma processing varies. For example, the processing control unit 242 sets the non-generation period to a period other than integer multiples of Tpla×V. For example, the processing control unit 242 controls the length of the non-generation period to be at least 1% different from the integer multiples of Tpla×V. When a purge period such as steps S2 and S4 is included in the non-generation period such as in PEALD, the processing control unit 242 controls the length of the purge period. For example, the processing control unit 242 controls the length of the purge period such that the rotation position of the stage 102 at the start timing of each generation period in step S3 varies. For example, the processing control unit 242 extends one or both of the purge periods in steps S2 and S4 such that the non-generation period is at least 1% different from the integer multiples of Tpla×V.

In this way, the rotation position of the stage 102 at the start timing of each generation period may be shifted, enabling the rotation position in the initial state immediately after plasma generation to be shifted, which may prevent non-uniform plasma processing results for the substrate W. It is desirable that the rotation position in the initial state immediately after plasma generation is shifted uniformly across the entire circumference when all cycles in the recipe data 231 are completed by shifting the rotation position for each cycle.

As described above, the plasma processing apparatus 100 according to the first embodiment includes the stage 102, the rotational drive mechanism 121, the microwave introduction device 105 (generator), the acquisition unit 241, and the processing control unit 242. The stage 102 is located inside the processing container 101 and is configured to place the substrate W thereon. The rotational drive mechanism 121 is configured to rotationally drive the stage 102. The microwave introduction device 105 is attached to a wall portion of the processing container 101 facing the stage 102 and is configured to enable plasma generation inside the processing container 101. The acquisition unit 241 is configured to acquire the recipe data 231 including a generation period and the rotation speed of the stage 102, the recipe data 231 being processing conditions for a plasma processing in which the generation period during which a plasma is generated inside the processing container 101 and a non-generation period during which no plasma is generated are alternately repeated a plurality of times. The processing control unit 242 is configured to control at least one of the plasma generation period by the microwave introduction device 105 and the rotation speed of the stage 102, to ensure that the stage 102 rotates N times (N is an integer of 1 or more) during plasma generation inside the processing container 101, when performing the plasma processing by generating a plasma inside the processing container 101 by the microwave introduction device 105 while rotating the stage 102 by the rotational drive mechanism 121 based on the recipe data 231 acquired by the acquisition unit 241. This allows the plasma processing apparatus 100 to equalize the amount of plasma irradiation in the circumferential direction of the substrate W.

Further, the processing control unit 242 is configured to correct at least one of the generation period and the rotation speed in the recipe data 231 acquired by the acquisition unit 241 to ensure that the stage 102 rotates N times during plasma generation inside the processing container 101, and to perform the plasma processing based on the corrected recipe data 231. This allows the plasma processing apparatus 100 to equalize the amount of plasma irradiation in the circumferential direction of the substrate W.

Further, the microwave introduction device 105 is configured such that the plasma distribution on the stage 102 exhibits rotational symmetry of M times (M is an integer of 2 or more) about the rotation axis of the stage 102. The processing control unit 242 is configured to correct at least one of the generation period and the rotation speed in the recipe data 231 acquired by the acquisition unit 241, to ensure that the stage 102 rotates N/M times during plasma generation inside the processing container 101. As such, when the plasma distribution corresponds to M-time rotational symmetry, the plasma processing apparatus 100 may equalize the amount of plasma irradiation in the circumferential direction of the substrate W by rotating the stage 102 N/M times during plasma generation.

Further, the processing control unit 242 is configured to calculate the number of rotations of the stage 102 during the generation period by multiplying the generation period and the rotation speed of the stage 102, to perform rounding of the calculated number of rotations to an integer of 1 or more, and to correct the rotation speed in the recipe data 231 to a value obtained by dividing the integer resulting from the rounding of the number of rotations by the generation period. This allows the plasma processing apparatus 100 to equalize the amount of plasma irradiation in the circumferential direction of the substrate W without changing the generation period in the recipe data 231.

Further, the processing control unit 242 is configured to calculate a multiplication value by multiplying the generation period, the rotation speed, and the rotational symmetry number M, to perform rounding of the calculated multiplication value to an integer of 1 or more, and to correct the rotation speed in the recipe data 231 to a value obtained by dividing the integer resulting from the rounding of the multiplication value by the generation period and the rotational symmetry number M. In this case as well, the plasma processing apparatus 100 may equalize the amount of plasma irradiation in the circumferential direction of the substrate W without changing the generation period in the recipe data 231.

Further, the rounding is one of truncation, rounding-up, and rounding to the nearest integer. This allows the plasma processing apparatus 100 to equalize the amount of plasma irradiation in the circumferential direction of the substrate W while minimizing a change in the rotation speed due to correction.

Further, the processing control unit 242 is configured to perform control to store the rotation position of the stage 102 at the start timing when the microwave introduction device 105 starts plasma generation inside the processing container 101, and to terminate the plasma generation by the microwave introduction device 105 at the timing when the rotation position of the stage 102 becomes the rotation position at the start timing after the generation period in the recipe data 231 has passed. This allows the plasma processing apparatus 100 to equalize the amount of plasma irradiation in the circumferential direction of the substrate W.

Further, the processing control unit 242 is configured to control the length of the non-generation period such that the rotation position of the stage 102 at the start timing of each generation period of the plasma processing varies, when performing the plasma processing based on the recipe data 231. This allows the plasma processing apparatus 100 to change the rotation position of the stage 102 at the start timing of each generation period to be different without changing the generation period, which may prevent non-uniform plasma processing results for the substrate W.

Further, the recipe data 231 includes a purge period for purging the inside of the processing container 101 during the non-generation period. The processing control unit 242 is configured to control the length of the purge period. This allows the plasma processing apparatus 100 to change the rotation position of the stage 102 at the start timing of each generation period to be different without changing the generation period, which may prevent non-uniform plasma processing results for the substrate W.

### Second Embodiment

Next, a second embodiment will be described. In the second embodiment, a case where the input of processing conditions is assisted when creating the recipe data 231 to ensure that the stage 102 rotates N times during plasma generation.

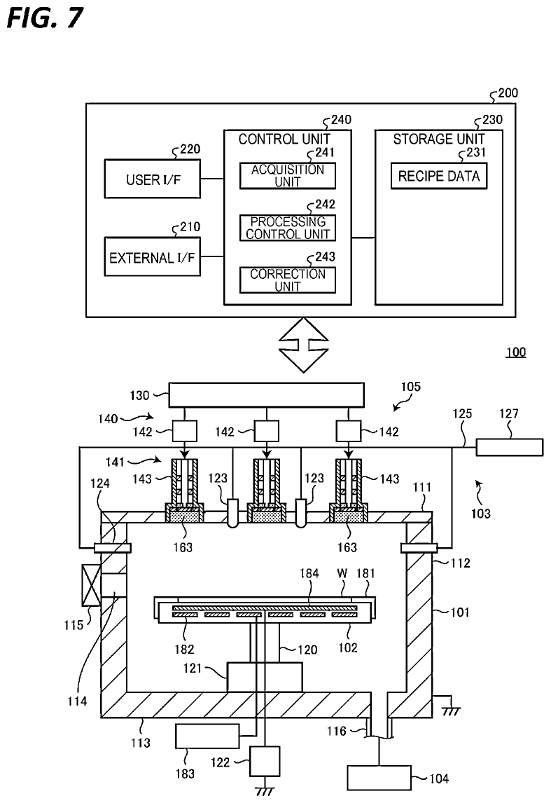

FIG. 7 is a cross-sectional view schematically illustrating an example of the plasma processing apparatus 100 according to a second embodiment. The plasma processing apparatus 100 according to the second embodiment has the same configuration as the first embodiment illustrated in FIG. 1, and thus, a description of the same parts will be omitted and differences will mainly be described.

The plasma processing apparatus 100 allows for the creation of the recipe data 231 by the controller 200. The controller 200 allows for the display of the recipe data 231 on the display of the user I/F 220 as well as the input of processing conditions from the input part of the user I/F 220. The controller 200 receives an input from the user I/F 220 including a generation period during which a plasma is generated inside the processing container 101 and the rotation speed of the stage 102 as plasma processing conditions. In the embodiment, the controller 200 corresponds to an information processing apparatus disclosed herein, and the user I/F 220 corresponds to a reception unit disclosed herein.

The control unit 240 further has the function of a correction unit 243. The correction unit 243 corrects at least one of the generation period and the rotation speed of the stage 102 as received from the user I/F 220, to ensure that the stage 102 rotates N times during plasma generation inside the processing container 101. For example, the correction unit 243 corrects at least one of the generation period and the rotation speed of the stage 102, to ensure that the stage 102 rotates N times during plasma generation inside the processing container 101, similar to the correction by the processing control unit 242 described above.

Once the connector 243 has corrected at least one of the generation period and the rotation speed of the stage 102, it displays the corrected information on the display of the user I/F 220 in a distinguishable manner. For example, once the correction unit 243 has corrected the rotation speed of the stage 102, it displays the corrected rotation speed on the display of the user I/F 220 in a distinguishable manner. This allows for the identification of the corrected information.

The controller 200 receives an input from the user I/F 220 to confirm the plasma processing conditions. When the user I/F 220 receives a confirmation instruction, the controller 200 stores the confirmed processing conditions in the recipe data 231. When the user I/F 220 receives the confirmation instruction, the correction unit 243 may correct at least one of the generation period and the rotation speed of the stage 102 received from the user I/F 220 and store the corrected information in the recipe data 231.

When the plasma processing apparatus 100 has performed a plasma processing based on this recipe data 231, the stage 102 rotates N times during plasma generation inside the processing container 101, which may allow for equalizing the amount of plasma irradiation in the circumferential direction of the substrate W.

When the plasma distribution exhibits M-time rotational symmetry, the correction unit 243 may correct at least one of the plasma generation period and the rotation speed of the stage 102, to ensure that the stage 102 rotates N/M times during plasma generation inside the processing container 101.

Further, a case where the recipe data 231 is created by the controller 200 of the plasma processing apparatus 100 has been described by way of example. However, the specified technology is not limited to this. The recipe data 231 may be created with another information processing apparatus. In this case, when creating the recipe data 231 in the other information processing apparatus, at least one of the generation period and the rotation speed of the stage 102 may be corrected as described above.

### [Correction Method]

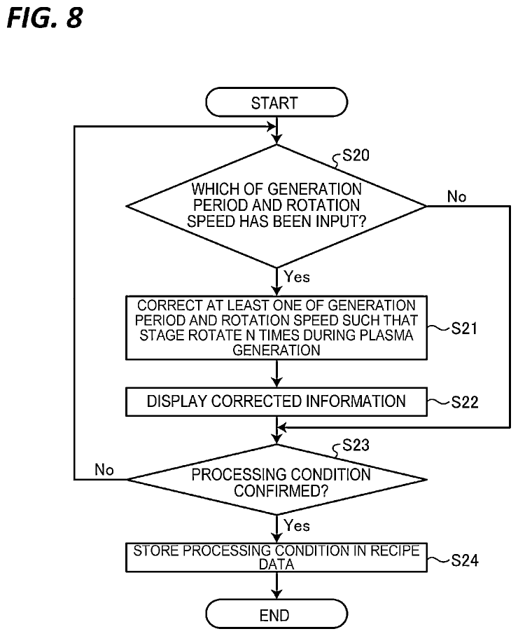

Next, the flow of a correction method according to the second embodiment will be described. FIG. 8 is a flowchart illustrating an example of the flow of a correction method according to the embodiment. A processing in FIG. 8 is executed when plasma processing conditions are input.

The correction unit 243 determines whether either a generation period during which a plasma is generated inside the processing container 101 or the rotation speed of the stage 102 has been input as plasma processing conditions from the user I/F 220 (step S20). When neither has been input (step S20: No), the processing proceeds to step S23, which will be described later.

Meanwhile, when either one has been input (step S20: Yes), the correction unit 243 corrects at least one of the generation period and the rotation speed of the stage 102, to ensure that the stage 102 rotates N times during plasma generation inside the processing container 101 (step S21).

Once the connector 243 has corrected at least one of the generation period and the rotation speed of the stage 102, it displays the corrected information on the display of the user I/F 220 in a distinguishable manner (step S22).

The controller 200 determines whether a confirmation instruction of processing conditions has been input (step S23). when the confirmation instruction has not been input, the processing proceeds to step S20 described above.

Meanwhile, when the confirmation instruction has been input, the controller 200 stores the confirmed processing conditions in the recipe data 231 (step S25) and terminates the processing as illustrated in this flowchart.

As described above, the controller 200 (information processing apparatus) according to the second embodiment includes the user I/F 220 (reception unit) and the correction unit 243. The user I/F 220 is configured to receive the input of the generation period and the rotation speed of the stage 102 as processing conditions for a plasma processing in which a generation period during which a plasma is generated inside the processing container 101 and a non-generation period during which no plasma is generated are alternately repeated a plurality of times while rotating the stage 102, which is located inside the processing container 101 to place the substrate W thereon. The correction unit 243 is configured to correct at least one of the generation period and the rotation speed of the stage 102 as received from the user I/F 220, to ensure that the stage 102 rotates N times (N is an integer of 1 or more) during plasma generation inside the processing container 101. This allows the controller 200 to equalize the amount of plasma irradiation in the circumferential direction of the substrate W.

Although the embodiments have been described above, the embodiments disclosed herein should be considered to be exemplary and not restrictive in all respects. In fact, the above-described embodiments may be implemented in various forms. Further, the above-described embodiments may be omitted, replaced, or modified in various ways without departing from the scope and spirit of the appended claims.

For example, in the above embodiment, a case where the substrate W is a semiconductor wafer has been described by way of example, but the disclosure is not limited to this. The substrate W may be of any type.

Further, in the above embodiment, a case where a plasma is generated using microwaves has been described by way of example, but the disclosure is not limited to this. The plasma may be generated using any method. For example, the plasma processing apparatus 100 may be any type of plasma processing apparatus such as capacitively coupled plasma (CCP), inductively coupled plasma (ICP), microwave excited surface wave plasma (SWP), or electron cyclotron resonance plasma (ECP).

Further, in the above embodiment, a case where film formation as a plasma processing is performed on the substrate W by way of example, but the disclosure is not limited to this. Any plasma processing may be used as long as it is a processing using a plasma. For example, the plasma processing may be etching, modification, or thermal processing such as ashing.

The following appendices regarding the above embodiments are further disclosed.

### Appendix 1

A plasma processing apparatus comprising:
a stage located inside a processing container and configured to place a substrate thereon;
a rotational driver configured to rotationally drive the stage;
a generator attached to a wall portion of the processing container facing the stage and configured to generate plasma inside the processing container; and
a controller configured to control overall operation of the plasma processing apparatus,
wherein the controller includes
an acquisition circuitry configured to acquire a processing condition including a generation period and a rotation speed of the stage as the processing condition for a plasma processing in which the generation period during which plasma is generated inside the processing container and a non-generation period during which no plasma is generated are alternately repeated a plurality of times; and
a processing control circuitry configured to control at least one of the generation period by the generator and the rotation speed such that the stage rotates N times (N is an integer of 1 or more) during generation of the plasma inside the processing container, when the plasma processing is performed by generating the plasma inside the processing container by the generator while rotating the stage by the rotational driver based on the processing condition acquired by the acquisition circuitry.

### Appendix 2

The plasma processing apparatus described in Appendix 1, wherein the processing control circuitry is configured to correct at least one of the generation period and the rotation speed of the processing condition acquired by the acquisition circuitry such that the stage rotates N times during generation of the plasma inside the processing container, and to perform the plasma processing based on the corrected processing condition.

### Appendix 3

The plasma processing apparatus described in Appendix 2, wherein the generator is configured such that plasma distribution on the stage exhibits rotational symmetry of M times (M is an integer of 2 or more) about a rotation axis of the stage, and the processing control circuitry is configured to correct at least one of the generation period and the rotation speed of the processing condition acquired by the acquisition circuitry such that the stage rotates N/M times during the generation of the plasma inside the processing container.

### Appendix 4

The plasma processing apparatus described in Appendix 2, wherein the processing control circuitry is configured to calculate a number of rotations of the stage during the generation period by multiplying the generation period and the rotation speed, perform rounding of the calculated number of rotations to an integer of 1 or more, and correct the rotation speed of the processing condition to a value obtained by dividing the integer resulting from the rounding of the number of rotations by the generation period.

### Appendix 5

The plasma processing apparatus described in Appendix 3, wherein the processing control circuitry is configured to calculate a multiplication value by multiplying the generation period, the rotation speed, and a rotational symmetry number M, perform rounding of the calculated multiplication value to an integer of 1 or more, and correct the rotation speed of the processing condition to a value obtained by dividing the integer resulting from the rounding of the multiplication value by the generation period and the rotational symmetry number M.

### Appendix 6

The plasma processing apparatus described in Appendix 4 or 5, wherein the rounding is any of truncation, rounding-up, or rounding to a nearest decimal.

### Appendix 7

The plasma processing apparatus described in Appendix 1, wherein the processing control circuitry is configured to perform control to store a rotation position of the stage at a start timing when the generator starts plasma generation inside the processing container, and to terminate the plasma generation by the generator at a timing when the rotation position of the stage becomes the rotation position at the start timing after the generation period of the processing condition elapses.

### Appendix 8

The plasma processing apparatus described in any one of Appendixes 1 to 7, wherein the processing control circuitry is configured to control a length of the non-generation period such that the rotation position of the stage at a start timing of each generation period of the plasma processing varies, when the plasma processing is performed based on the processing condition.

### Appendix 9

The plasma processing apparatus described in Appendix 8, wherein the processing condition includes a purge period for purging an inside of the processing container during the non-generation period, and the processing control circuitry is configured to control a length of the purge period.

### Appendix 10

An information processing apparatus comprising:
a reception circuitry configured to receive an input of a generation period and a rotation speed of a stage as a processing condition for a plasma processing in which the generation period during which a plasma is generated inside a processing container and a non-generation period during which no plasma is generated are alternately repeated a plurality of times while rotating the stage, the stage being located inside the processing container and configured to place a substrate thereon; and
a correction circuitry configured to correct at least one of the generation period and the rotation speed received from the reception circuitry such that the stage rotates N times (N is an integer of 1 or more) during generation of the plasma inside the processing container.

### Appendix 11

A plasma processing method comprising:
(a) providing a plasma processing apparatus including
   a stage located inside a processing container and configured to place a substrate thereon;
   a rotational driver configured to rotationally drive the stage; and
   a generator attached to a wall portion of the processing container facing the stage and configured to generate plasma inside the processing container;
(b) acquiring a processing condition including a generation period and a rotation speed of the stage as the processing condition for a plasma processing in which the generation period during which plasma is generated inside the processing container and a non-generation period during which no plasma is generated are alternately repeated a plurality of times; and
(c) controlling at least one of the generation period by the generator and the rotation speed such that the stage rotates N times (N is an integer of 1 or more) during generation of the plasma inside the processing container, when the plasma processing is performed by generating the plasma inside the processing container by the generator while rotating the stage by the rotational driver based on the processing condition acquired in (b).

### Appendix 12

A correction method comprising:
(a) receiving, by a reception circuitry, an input of a generation period and a rotation speed of a stage as a processing condition for a plasma processing in which the generation period during which a plasma is generated inside a processing container and a non-generation period during which no plasma is generated are alternately repeated a plurality of times while rotating the stage, the stage being located inside the processing container and configured to place a substrate thereon; and
(b) correcting at least one of the generation period and the rotation speed received from the reception circuitry such that the stage rotates N times (N is an integer of 1 or more) during generation of the plasma inside the processing container.

According to the present disclosure, it is possible to equalize the amount of plasma irradiation in the circumferential direction of a substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a stage located inside a processing container and configured to place a substrate thereon;
a rotational driver configured to rotationally drive the stage;
a generator attached to a wall portion of the processing container facing the stage and configured to generate plasma inside the processing container; and
a controller configured to control overall operation of the plasma processing apparatus,
wherein the controller includes
an acquisition circuitry configured to acquire a processing condition including a generation period and a rotation speed of the stage as the processing condition for a plasma processing in which the generation period during which plasma is generated inside the processing container and a non-generation period during which no plasma is generated are alternately repeated a plurality of times; and
a processing control circuitry configured to control at least one of the generation period by the generator and the rotation speed such that the stage rotates N times (N is an integer of 1 or more) during generation of the plasma inside the processing container, when the plasma processing is performed by generating the plasma inside the processing container by the generator while rotating the stage by the rotational driver based on the processing condition acquired by the acquisition circuitry.

2. The plasma processing apparatus according to claim 1, wherein the processing control circuitry is configured to correct at least one of the generation period and the rotation speed of the processing condition acquired by the acquisition circuitry such that the stage rotates N times during generation of the plasma inside the processing container, and to perform the plasma processing based on the corrected processing condition.

3. The plasma processing apparatus according to claim 2, wherein the generator is configured such that plasma distribution on the stage exhibits rotational symmetry of M times (M is an integer of 2 or more) about a rotation axis of the stage, and
the processing control circuitry is configured to correct at least one of the generation period and the rotation speed of the processing condition acquired by the acquisition circuitry such that the stage rotates N/M times during the generation of the plasma inside the processing container.

4. The plasma processing apparatus according to claim 2, wherein the processing control circuitry is configured to calculate a number of rotations of the stage during the generation period by multiplying the generation period and the rotation speed, perform rounding of the calculated number of rotations to an integer of 1 or more, and correct the rotation speed of the processing condition to a value obtained by dividing the integer resulting from the rounding of the number of rotations by the generation period.

5. The plasma processing apparatus according to claim 3, wherein the processing control circuitry is configured to calculate a multiplication value by multiplying the generation period, the rotation speed, and a rotational symmetry number M, perform rounding of the calculated multiplication value to an integer of 1 or more, and correct the rotation speed of the processing condition to a value obtained by dividing the integer resulting from the rounding of the multiplication value by the generation period and the rotational symmetry number M.

6. The plasma processing apparatus according to claim 4, wherein the rounding is any of truncation, rounding-up, or rounding to a nearest decimal.

7. The plasma processing apparatus according to claim 1, wherein the processing control circuitry is configured to perform control to store a rotation position of the stage at a start timing when the generator starts plasma generation inside the processing container, and to terminate the plasma generation by the generator at a timing when the rotation position of the stage becomes the rotation position at the start timing after the generation period of the processing condition elapses.

8. The plasma processing apparatus according to claim 1, wherein the processing control circuitry is configured to control a length of the non-generation period such that the rotation position of the stage at a start timing of each generation period of the plasma processing varies, when the plasma processing is performed based on the processing condition.

9. The plasma processing apparatus according to claim 8, wherein the processing condition includes a purge period for purging an inside of the processing container during the non-generation period, and
the processing control circuitry is configured to control a length of the purge period.

10. An information processing apparatus comprising:
a reception circuitry configured to receive an input of a generation period and a rotation speed of a stage as a processing condition for a plasma processing in which the generation period during which a plasma is generated inside a processing container and a non-generation period during which no plasma is generated are alternately repeated a plurality of times while rotating the stage, the stage being located inside the processing container and configured to place a substrate thereon; and
a correction circuitry configured to correct at least one of the generation period and the rotation speed received from the reception circuitry such that the stage rotates N times (N is an integer of 1 or more) during generation of the plasma inside the processing container.

11. A plasma processing method comprising:
(a) providing a plasma processing apparatus including a stage located inside a processing container and configured to place a substrate thereon;
a rotational driver configured to rotationally drive the stage; and
a generator attached to a wall portion of the processing container facing the stage and configured to generate plasma inside the processing container;
(b) acquiring a processing condition including a generation period and a rotation speed of the stage as the processing condition for a plasma processing in which the generation period during which plasma is generated inside the processing container and a non-generation period during which no plasma is generated are alternately repeated a plurality of times; and
(c) controlling at least one of the generation period by the generator and the rotation speed such that the stage rotates N times (N is an integer of 1 or more) during generation of the plasma inside the processing container, when the plasma processing is performed by generating the plasma inside the processing container by the generator while rotating the stage by the rotational driver based on the processing condition acquired in (b).

12. A correction method comprising:
(a) receiving, by a reception circuitry, an input of a generation period and a rotation speed of a stage as a processing condition for a plasma processing in which the generation period during which a plasma is generated inside a processing container and a non-generation period during which no plasma is generated are alternately repeated a plurality of times while rotating the stage, the stage being located inside the processing container and configured to place a substrate thereon; and
(b) correcting at least one of the generation period and the rotation speed received from the reception circuitry such that the stage rotates N times (N is an integer of 1 or more) during generation of the plasma inside the processing container.
